(19) United States
(12) Patent Application Publication
(10) Pub. No.: US 2026/0136787 A1
(43) Pub. Date: May 14, 2026

(54) ELEMENT SUBSTRATE AND MODULE

(71) Applicant: CANON KABUSHIKI KAISHA, Tokyo (JP)

(72) Inventor: HIDEMASA OSHIGE, Kanagawa (JP)

(21) Appl. No.: 19/377,429

(22) Filed: Nov. 3, 2025

(30) Foreign Application Priority Data
Nov. 13, 2024 (JP) 2024-197910
Aug. 19, 2025 (JP) 2025-136387

(51) Int. Cl. H10K 59/131; H10K 59/12; H10K 59/88

(52) U.S. Cl. CPC H10K 59/131; H10K 59/1201; H10K 59/88

(57) ABSTRACT

In an element substrate having an effective element region and a peripheral region disposed around the effective element region, a slit is provided in an insulating layer along an edge of the substrate in a plan view, and a resin layer is disposed in the slit.

### BACKGROUND

### Field of the Technology

The present disclosure relates to an element substrate and a module.

### Description of the Related Art

Regarding an element substrate for imaging or display includes elements, wiring layers, and a sealing layer for suppressing the entry of moisture and oxygen into the elements, on a substrate, when a wafer is diced, that is, cut and separated into individual element substrates, the sealing layers can peel off from the ends of the element substrates to impair the sealing performance. Japanese Patent Laid-Open No. 2011-009795 discusses providing a slit where the sealing layer is removed near the end of the element substrate.

### SUMMARY

When an external force or impact is applied to the slit of the sealing layer, the sealing layer or an insulating layer beneath the sealing layer may peel off from the slit, thereby reducing yield.

An aspect of the present disclosure provides an element substrate that includes a plurality of function elements arranged to form an effective element region, and a peripheral region along a surface of the element substrate. The peripheral region surrounds the effective element region. The element substrate includes a wiring layer electrically connected to the plurality of function elements, an external connecting terminal, and an insulating layer covering the function elements and the wiring layer. The insulating layer has a slit between the external connecting terminal and an edge of the element substrate. Resin is disposed in the slit.

Aspects of the present disclosure relate to a module. The module includes the element substrate and a circuit substrate joined via a joining member to the external connecting terminal of the element substrate.

Features of the present disclosure will become apparent from the following description of embodiments with reference to the attached drawings. The following description of embodiments are described by way of example.

### BRIEF DESCRIPTION OF THE DRAWINGS

FIG. 1A is a schematic plan view that shows the configuration of a module according to a first embodiment of the present disclosure, and FIG. 1B is a schematic cross-sectional view taken along the line IB-IB in FIG. 1A.

FIGS. 2A to 2E are schematic cross-sectional views that illustrate a manufacturing process for an element substrate of the module shown in FIGS. 1A and 1B.

FIG. 3A is a schematic plan view that shows the configuration of a module according to a second embodiment of the present disclosure, and FIG. 3B is a schematic cross-sectional view taken along the line IIIB-IIIB in FIG. 3A.

FIGS. 4A to 4E are schematic cross-sectional views that illustrate a manufacturing process for an element substrate of the module shown in FIGS. 3A and 3B.

FIG. 5A is a schematic plan view that shows the configuration of a module according to a third embodiment of the present disclosure, and FIG. 5B is a schematic cross-sectional view taken along the line VB-VB in FIG. 5A.

FIG. 6A is a schematic plan view that shows the configuration of a module according to a fourth embodiment of the present disclosure, and FIG. 6B is a schematic cross-sectional view taken along the line VIB-VIB in FIG. 6A.

FIG. 7A is a schematic cross-sectional view that shows an example of a pixel of a display apparatus according to an embodiment of the present disclosure. FIG. 7B is a schematic cross-sectional view of an example of the display apparatus according to the embodiment of the present disclosure.

FIG. 8 is a schematic exploded perspective view that shows an example of the display apparatus according to the embodiment of the present disclosure.

FIG. 9A is a schematic view that shows an example of an image capturing apparatus according to an embodiment of the present disclosure. FIG. 9B is a schematic view that shows an example of an electronic device according to an embodiment of the present disclosure.

FIG. 10A is a schematic view that shows an example of the display apparatus according to the embodiment of the present disclosure, and FIG. 10B is a schematic view that shows an example of a foldable display apparatus.

FIG. 11 is a schematic exploded perspective view that shows an example of an illumination apparatus according to an embodiment of the present disclosure.

FIG. 12A is a schematic view that shows an example of an automobile equipped with a vehicle lamp according to an embodiment of the present disclosure, and FIG. 12B is a schematic view that shows an example of the automobile equipped with the vehicle lamp according to the embodiment of the present disclosure.

FIG. 13A is a schematic view that shows an example of a wearable device according to an embodiment of the present disclosure, and FIG. 13B is a schematic view that shows an example of the wearable device according to the embodiment of the present disclosure and that shows a mode with an image capturing apparatus.

FIG. 14A is a schematic view that shows an example of an image forming apparatus according to an embodiment of the present disclosure, FIG. 14B is a schematic view that shows an example of an exposure light source of the image forming apparatus according to the embodiment of the present disclosure, and FIG. 14C is a schematic view that shows an example of the exposure light source of the image forming apparatus according to the embodiment of the present disclosure.

### DESCRIPTION OF THE EMBODIMENTS

Hereinafter, embodiments of the present disclosure will be described with reference to the attached drawings. In the following description and drawings, similar reference numbers are assigned to common components in the drawings. Therefore, common components will be described with reference to the drawings, and the description of components with common reference numbers is incorporated by reference without being repeated, for conciseness.

### First Embodiment

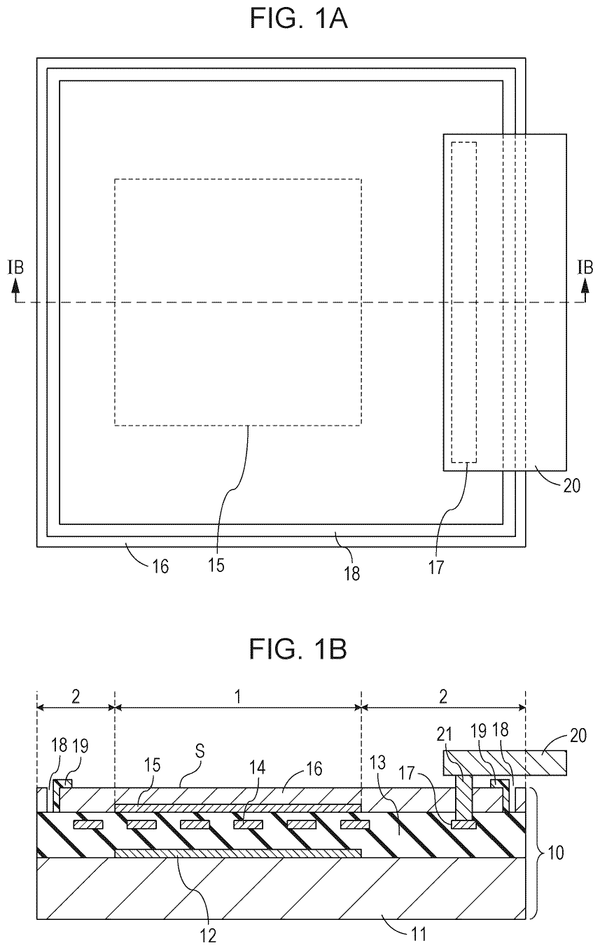

FIGS. 1A and 1B are schematic views illustrating the first embodiment of a module including an element substrate.

FIG. 1A is a schematic plan view of the module relative to a surface S. FIG. 1B is a schematic cross-sectional view taken along the line IB-IB in FIG. 1A. In the present disclosure, the layout in a plan view is a layout when the module is viewed in a direction perpendicular to the surface S (a normal direction of the surface S) of the module, and it is assumed that overlapping components can be seen through.

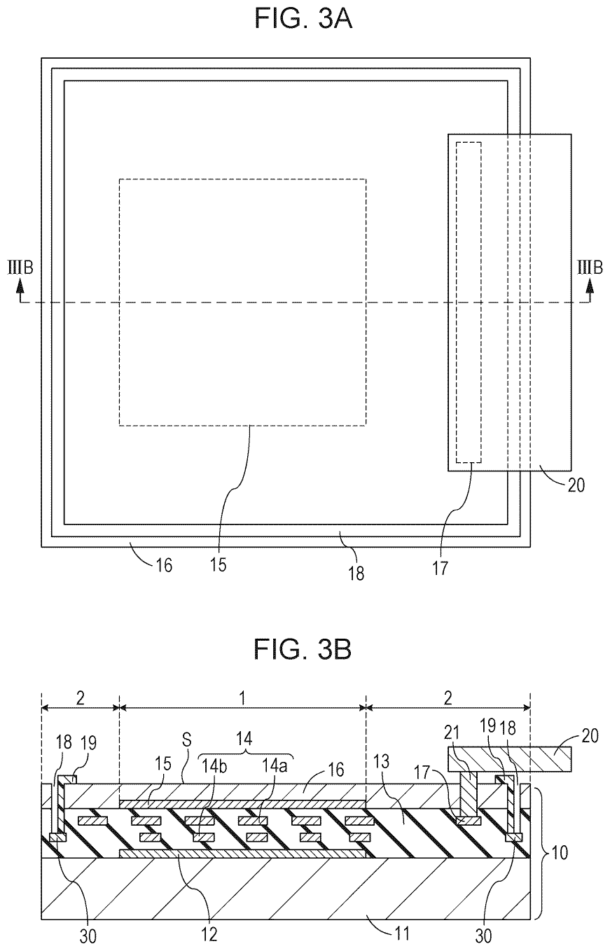

For clarity, FIG. 1A does not show each of the members shown in FIG. 1B, and FIGS. 3A, 3B, 5A, 5B, 6A, and 6B (described later) are similarly provided.

The module of the present embodiment is includes an element substrate 10 and a circuit substrate 20, and the circuit substrate 20 is joined to the element substrate 10. The element substrate 10 has an effective element region 1 and a peripheral region 2 on one surface of a substrate 11. A semiconductor element 12 and a function element 15 are provided in the effective element region 1. The peripheral region 2 is positioned around the effective element region 1. The effective element region 1 has a quadrilateral shape, and the diagonal length of the effective element region 1, for example, ranges from 5 mm to 50 mm. The peripheral region 2 can include a peripheral circuit region where peripheral circuits are disposed. When, for example, the element substrate 10 is a display substrate, the peripheral circuits include a drive circuit for driving effective pixels and a processing circuit, such as a digital-to-analog conversion circuit (DAC), that processes signals input to the effective pixels. The peripheral region 2 is positioned outside the effective element region 1 and can include a non-effective element region where non-effective elements are provided. Non-effective elements are dummy elements, reference elements, test elements, monitor elements, and the like that do not function as effective elements.

The peripheral region 2 includes a terminal region where a plurality of external connecting terminals 17 for joining to the circuit substrate 20 is provided. In the peripheral region 2, a slit 18 is provided in an insulating layer 16, and a resin layer 19 is disposed at least in part of the slit 18. The insulating layer 16 can function as a protective layer. The slit 18 can be formed linearly and continuously along the outermost periphery of the element substrate 10 in a plan view from the viewpoint of suppressing the peeling of the insulating layer 16. Alternatively, the slit 18 may be formed intermittently, e.g., a dashed line.

The external connecting terminals 17 are provided between the effective element region 1 and the slit 18. In the effective element region 1 of the element substrate 10, the semiconductor element 12 is disposed, and an insulating layer 13 covers the semiconductor element 12. A wiring layer 14 is disposed within the insulating layer 13, a function element 15 is provided on the insulating layer 13, and the insulating layer 16 covers the function element 15.

The function element 15 is a solid state image pickup element, a display element, a photoelectric conversion element, or the like. FIG. 1B shows the position where the function element 15 is a display element or a photoelectric conversion element. When the function element 15 is a solid state image pickup element, the function element 15 is provided between the insulating layer 13 and the substrate 11 as in the case of the semiconductor element 12, and at least a part of the function element 15 is provided within the substrate 11. When the function element 15 is a display element, the function element 15 is an EL element in an electroluminescence display (ELD), a liquid crystal element in a liquid crystal display (LCD), or a reflective element in a digital mirror device (DMD).

The insulating layer 16 is provided on the function element 15 in the effective element region 1 and on the insulating layer 13 in the peripheral region 2. As long as the insulating layer 16 is an insulating film, the insulating layer 16 may be a single layer or may have a layered structure of a plurality of insulating films. The thickness of the insulating layer 16 is greater than or equal to 1 μm, in consideration of moisture and oxygen barrier performance to the function element 15, and is less than or equal to 10 μm, in consideration of a removal time of the insulating layer in the step of forming the slit 18.

The external connecting terminals 17 and peripheral circuits are provided in the peripheral region 2 of the element substrate 10.

An opening is provided in the insulating layer 13 and the insulating layer 16 on or above the external connecting terminal 17, and the circuit substrate 20 is joined to the exposed external connecting terminal 17 via the joining member 21.

The insulating layer 16 has the slit 18, the insulating layer 16 being completely removed at the slit 18, exposing the insulating layer 13 at the bottom surface of the slit 18. By providing the slit 18 in the insulating layer 16, peeling of the insulating layer 16 from the edge of the element substrate 10 on the insulating layer 13, as may occur due to impact during dicing, may be suppressed. The peeling may progress to the effective element region 1 when a wafer is diced into individual element substrates 10. From the viewpoint of suppressing the extension of peeling of the insulating layer 16 from the edge of the element substrate 10, the slit 18 can be provided near the edge of the element substrate 10. The width of the slit 18, for example, ranges from 0.5 μm to 100 μm. The width of the slit 18 is greater than or equal to 3 μm, in consideration of the dam effect of the resin layer 19 in a third embodiment (described later), and is less than or equal to 10 μm, from the viewpoint of a reduction in the size of the peripheral region 2.

The resin layer 19 is disposed in the slit 18, and at least the side surface of the slit 18 closer to the effective element region 1 is covered with the resin layer 19. By covering the side surface of the slit 18 with the resin layer 19, the peeling of the insulating layer 16 from the slit 18 may be suppressed when an external force is applied to the slit 18 in a module assembly process. When a metal pattern inside the insulating layer 13 is exposed at the opening portion of the slit 18, corrosion and dissolution of a metal pattern may be suppressed by providing the resin layer 19 in the slit 18. FIGS. 1A and 1B show a single slit 18. When two or more slits 18 are formed at a predetermined interval, the peeling of the insulating layer 16 is further effectively suppressed. When two or more slits 18 are formed, it is sufficient to provide the resin layer 19 at least at the slit 18 close to the effective element region 1. However, the resin layer 19 may span all of the two or more slits in order to suppress the peeling of the insulating layer 16 between the slits. In this way, the element substrate of the present embodiment can suppress the extension of peeling of the insulating layer 16 during dicing because the slit 18 is provided in the insulating layer 16.

By disposing the resin layer 19 in the slit 18 of the insulating layer 16, the peeling of the insulating layer 16 from the slit 18 is suppressed during the assembly process and improve the yield.

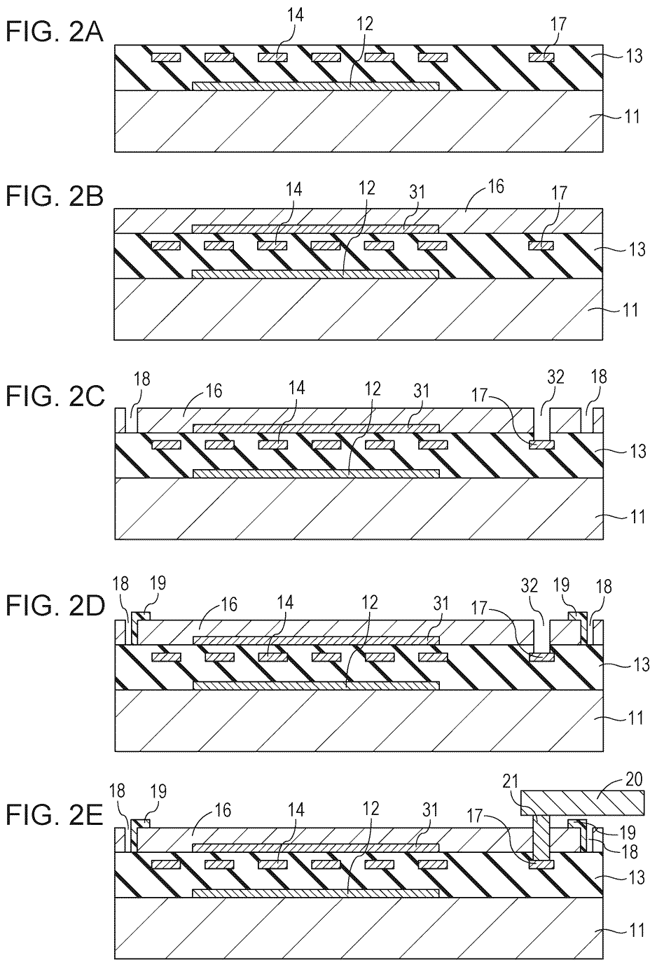

Next, a manufacturing process in a case where the function element 15 is an organic light emitting element (also referred to as an organic electroluminescence element or an organic EL element) will be described with reference to FIGS. 2A to 2E.

As shown in FIG. 2A, the semiconductor element 12 is initially provided on the substrate 11. The substrate 11 is made of a semiconductor material, such as single crystalline silicon. The semiconductor element 12 is a transistor or a diode, and at least part of the semiconductor element 12 is provided within the substrate 11. The insulating layer 13 is provided on the semiconductor element 12. The insulating layer 13 may include a plurality of insulating layers and may be made up of materials, such as a silicon oxide layer, a silicon nitride layer, and a silicon carbide layer. Silicon oxynitride and silicon carbonitride are regarded as a type of silicon nitride because both contain nitrogen and silicon as main elements.

The wiring layer 14 and the external connecting terminals 17 are provided within the insulating layer 13. Each wiring layer 14 includes a multilayer wiring layer made up of a metal member of aluminum, copper, or the like, via plugs, and contact plugs. To suppress metal diffusion to the insulating layer 13, a barrier metal, such as titanium (Ti), tantalum (Ta), titanium nitride (TiN), and tantalum nitride (TaN), may be provided at the interface between the insulating layer 13 and the wiring layer 14. The external connecting terminals 17 can be composed of the same layer as the wiring layer 14.

Subsequently, as shown in FIG. 2B, the organic light emitting element 31 is provided on the insulating layer 13 in the effective element region 1. The organic light emitting element 31 is electrically connected to at least the wiring layer 14 via a through-hole, and is further electrically connected to the semiconductor element 12 for driving the organic light emitting element 31 via the wiring layer 14. The organic light emitting element 31 includes a pixel electrode, a counter electrode, and an organic light emitting layer provided between the pixel electrode and a counter electrode. A pixel define layer is provided between adjacent organic light emitting elements 31 to reduce a short circuit between the elements due to a level difference of the pixel electrode. A hole injection layer and a hole transport layer may be formed between the organic light emitting layer and the pixel electrode to facilitate the injection and transport of holes from the pixel electrode. To facilitate the injection and transport of electrons from the counter electrode, an electron transport layer and an electron injection layer may be formed between the organic light emitting layer and the counter electrode.

Subsequently, the insulating layer 16 for sealing the organic light emitting element 31 from moisture and oxygen is provided on the organic light emitting element 31. The insulating layer 16 may be a single layer or may have a layered structure of a plurality of insulating films, as long as the insulating layer 16 is an insulating film. Because the slit 18 is formed in the insulating layer 16 in a later step, silicon nitride that can be processed to form the slit 18 by dry etching. A high moisture barrier performance can be used. A color filter layer, a lens structure, or the like can also be provided on the insulating layer 16.

Subsequently, as shown in FIG. 2C, the slit 18 is provided in the insulating layer 16 by a method, such as dry etching. A hole 32 is formed in the insulating layer 16 and insulating layer 13 on or above the external connecting terminal 17 using a method, such as dry etching, to expose the external connecting terminal 17. Etching to form the hole 32 and etching to form the slit 18 may be performed in the same step.

Subsequently, as shown in FIG. 2D, the resin layer 19 is disposed in the slit 18. The resin layer 19 covers at least the side surface of the slit 18, closer to the effective element region 1. A selected resin material, such as acrylic resin, epoxy resin, urethane resin, and silicone resin, can be used, and the resin layer 19 is formed to cover the slit 18 using a method such as dispensing and screen printing. A resin layer curing time can reduce by using a UV curing resin for the resin layer 19. By covering the side surface of the slit 18 with the resin layer 19 in a position close to the effective element region 1, the occurrence and progress of the peeling of the insulating layer 16 from the side surface of the slit 18 is suppressed.

In FIG. 2D, the resin layer 19 does not completely cover the inside of the slit 18; however, when the resin layer 19 is formed so as to bury the inside of the slit 18, it can suppress corrosion and dissolution of a metal pattern provided within the insulating layer 13 due to permeation of moisture from the slit 18.

Subsequently, as shown in FIG. 2E, the circuit substrate 20 and the external connecting terminal 17 exposed inside the hole 32 are electrically joined to each other via the joining member 21. Here, the circuit substrate 20 is, for example, a flexible printed circuit board (FPC), and the joining member 21 is an anisotropic conductive resin (ACF) or a solder bump. An ACF is a material in which conductive particles are contained in a binder made of thermosetting epoxy resin or acrylic resin. Conductive particles are sandwiched between terminals and fixedly cured by thermally compressing the circuit substrate 20 to the external connecting terminal 17 via the ACF, to achieve electrical continuity. Gold (Au) wire or copper (Cu) wire can be used as the joining member 21, and the external connecting terminal 17 and the circuit substrate 20 may be electrically bonded using such wires.

The organic EL display module of the present embodiment is completed through the above process.

### Second Embodiment

Another embodiment of the module will be described with reference to FIGS. 3A and 3B. The description of the configuration, functions, materials, advantageous effects, and the like, similar to those of the first embodiment is incorporated by reference without being repeated, for conciseness.

FIGS. 3A and 3B are schematic views illustrating the second embodiment of a module including an element substrate. FIG. 3A is a schematic plan view of the module relative to a surface S. FIG. 3B is a schematic cross-sectional view taken along the line IIIB-IIIB in FIG. 3A.

In the second embodiment, the slit 18 is provided extending from the upper surface of the insulating layer 16 to a partial depth of the insulating layer 13. The slit 18 can be formed linearly and continuously along the outermost periphery of the element substrate 10 in a plan view from the viewpoint of suppressing the peeling of the insulating layer 16. Alternatively, the slit 18 may be formed intermittently, e.g., as a dashed line.

The insulating layer 16 and part of the insulating layer 13 are removed at the slit 18, and the bottom portion of the slit 18 is present within the insulating layer 13. By providing the slit 18 that extends from the insulating layer 16 to the inside of the insulating layer 13, the peeling of the insulating layer 16 or the insulating layer 13 from the edge of the element substrate 10 due to impact during dicing and the progress of the peeling to the effective element region 1 when a wafer is diced into individual element substrates 10 is suppressed. To control the depth of the slit 18, an etching stopper film 30 can be provided within the insulating layer 13 at a position where the slit 18 is provided. The etching stopper film 30 can be disposed without increasing the number of steps by forming the etching stopper film 30 together with the same layer as the wiring layer 14. The position, shape, and dimensions of the slit 18 are similar to those of the first embodiment. Similar to the first embodiment, the resin layer 19 is disposed in the slit 18. The form of the resin layer 19 is similar to that of the first embodiment.

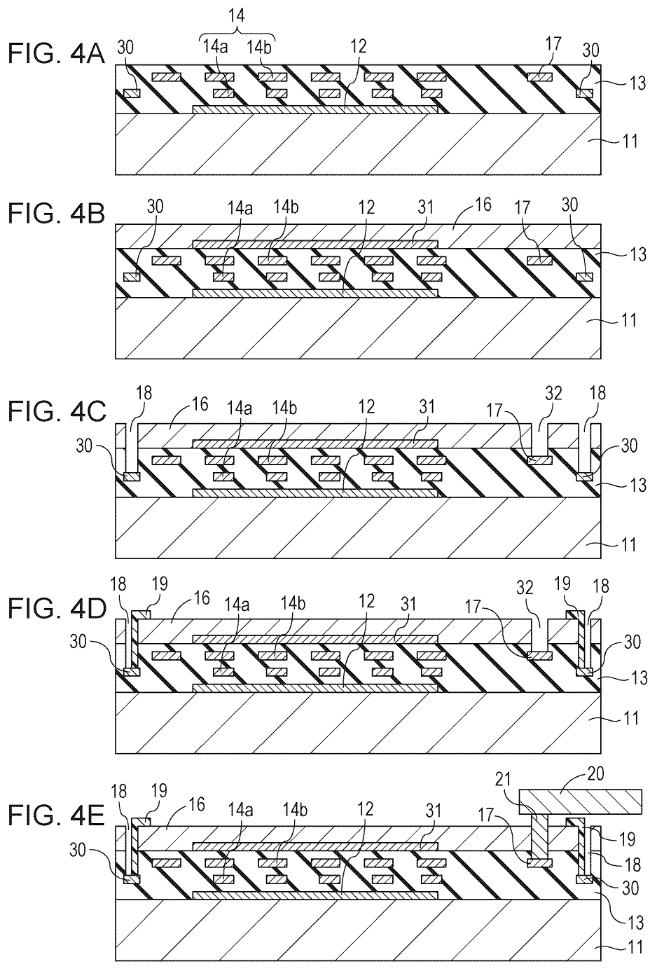

Next, a manufacturing process in a case where the function element 15 is an organic light emitting element will be described with reference to FIGS. 4A to 4E.

As shown in FIG. 4A, first, the semiconductor element 12 is provided on the substrate 11. The substrate 11 is made of a semiconductor material, such as single crystalline silicon. The semiconductor element 12 is a transistor or a diode, and at least part of the semiconductor element 12 is provided within the substrate 11. The insulating layer 13 is provided on the semiconductor element 12. The insulating layer 13 includes a plurality of insulating layers and is made up of materials, such as a silicon oxide layer, a silicon nitride layer, a silicon carbide layer, and low-dielectric-constant films called Low-k films, including silicon oxycarbide (SiOC), silicon oxyfluoride (SiOF), and organic polymers. Silicon oxynitride and silicon carbonitride are regarded as a type of silicon nitride because both contain nitrogen and silicon as main elements.

The wiring layer 14 including a first wiring layer 14a and a second wiring layer 14b, the external connecting terminals 17, and the etching stopper film 30 are provided within the insulating layer 13. Each of the first wiring layer 14a and the second wiring layer 14b includes a multilayer wiring layer made up of a metal member of aluminum, copper, or the like, via plugs, and contact plugs. To suppress metal diffusion to the insulating layer 13, a barrier metal, such as Ti, Ta, TiN, and TaN, may be provided at the interface between the insulating layer 13 and both the first wiring layer 14a and the second wiring layer 14b. The external connecting terminals 17 and the etching stopper film 30 may be provided as conductive layers along a same layer as the first wiring layer 14a and the second wiring layer 14b, respectively. When the etching stopper film 30 is formed from the same layer as the wiring layers 14a, 14b, one or some of aluminum, copper, titanium, and titanium nitride can be used as the materials of the layers.

In the present embodiment, the etching stopper film 30 is formed in the same layer as the first wiring layer 14a, and the external connecting terminals 17 are formed in the same layer as the second wiring layer 14b. Alternatively, the etching stopper film 30 and the external connecting terminals 17 may be formed in the same respective layers constituting a capacitive element. The layer that constitutes a specific capacitive element and that can be used as the etching stopper film 30 may be, for example, a single layer or a multiple layer of titanium nitride, zirconium oxide, or aluminum oxide. The etching stopper film 30 may be provided as a separate layer from the wiring layer 14 or the capacitive element. When the etching stopper film 30 is provided as a separate layer from the wiring layer 14, a material having a high etching selectivity ratio may be used when the slit is formed in the insulating layer 13. For example, when silicon oxide is used as the insulating layer 13, an insulating layer that has an insulating material, such as silicon nitride, silicon carbide, and aluminum oxide, may be used as the etching stopper film 30, and a conductive layer of aluminum nitride, silicon, or the like may be used. A transparent conductive film of indium tin oxide (ITO) or the like can be used. Therefore, an insulating layer that functions as the etching stopper film 30 may be disposed within the insulating layer 13.

Subsequently, as shown in FIG. 4B, the organic light emitting element 31 is provided on the insulating layer 13 in the effective element region 1. The organic light emitting element 31 is electrically connected to at least the wiring layer 14a or the wiring layer 14b via a through-hole, and is further electrically connected to the semiconductor element 12 for driving the organic light emitting element 31 via the wiring layer 14a or the wiring layer 14b.

Subsequently, as in the case of the first embodiment, the insulating layer 16 for sealing the organic light emitting element 31 from moisture and oxygen is provided on the organic light emitting element 31.

As shown in FIG. 4C, the slit 18 is provided from the surface of the insulating layer 16 into the insulating layer 13 by a method such as dry etching. A hole 32 is formed in the insulating layer 16 and insulating layer 13 on or above the external connecting terminal 17 using a method, such as dry etching, to expose the external connecting terminal 17. Etching to form the hole 32 and etching to form the slit 18 may be performed in the same step. At this time, the etching stopper film 30 made of a metal member, such as aluminum and copper, equivalent to the wiring layer 14a is formed on the bottom surface of the slit 18. When the slit 18 is formed using dry etching with etching gas, such as CF₄, C₄F₈, and CH₂F₂, aluminum and copper are almost not etched, so etching of the slit 18 can be stopped at the surface of the etching stopper film 30. In other words, the slit 18 is formed at a uniform depth so that the bottom portion of the slit 18 contacts with the surface of the etching stopper film 30.

In the present embodiment, the etching stopper film 30 is formed in the same layer as the first wiring layer 14a. Alternatively, the etching stopper film 30 may be formed in the same layer as the second wiring layer 14b. When the insulating layer 13 has a layered structure of a plurality of types of films, the slit 18 penetrates at least a film with the lowest adhesive force. Generally, a Low-k film is a porous material and with a low adhesive force to the upper and lower insulating layers, so peeling tends to occur at the interface between the Low-k film and the upper and lower layers during dicing. When, for example, a Low-k film is used as the insulating layer between the first wiring layer 14a and the second wiring layer 14b, the etching stopper film 30 is formed in the same layer as the first wiring layer 14a in a region where the slit 18 is provided, and the slit 18 is formed so as to extend from the surface of the insulating layer 16 to the surface of the etching stopper film 30 through the Low-k film that constitutes the insulating layer 13. Thus, the expansion of peeling at the slit 18 is suppressed even when the peeling progresses from the edge of the element substrate at the interface of the Low-k film during dicing. On the other hand, when the slit 18 extends completely through the insulating layer 13 to the substrate 11, the substrate 11 is exposed to an external environment, so chemical substances and metal elements may adhere to the surface of the substrate 11 from the external environment, with the result that the substrate surface may corrode or the metal elements diffuse into the semiconductor element region to degrade the characteristics of the semiconductor element. Thus, the insulating layer 13 can be left between the slit 18 and the substrate 11.

Subsequently, as shown in FIG. 4D, as in the case of the first embodiment, the resin layer 19 is disposed in the slit 18.

As shown in FIG. 4E, as in the case of the first embodiment, the external connecting terminal 17 exposed in the hole 32 is electrically joined to the circuit substrate 20 via the joining member 21.

The organic EL display module of the present embodiment is completed through the above process.

### Third Embodiment

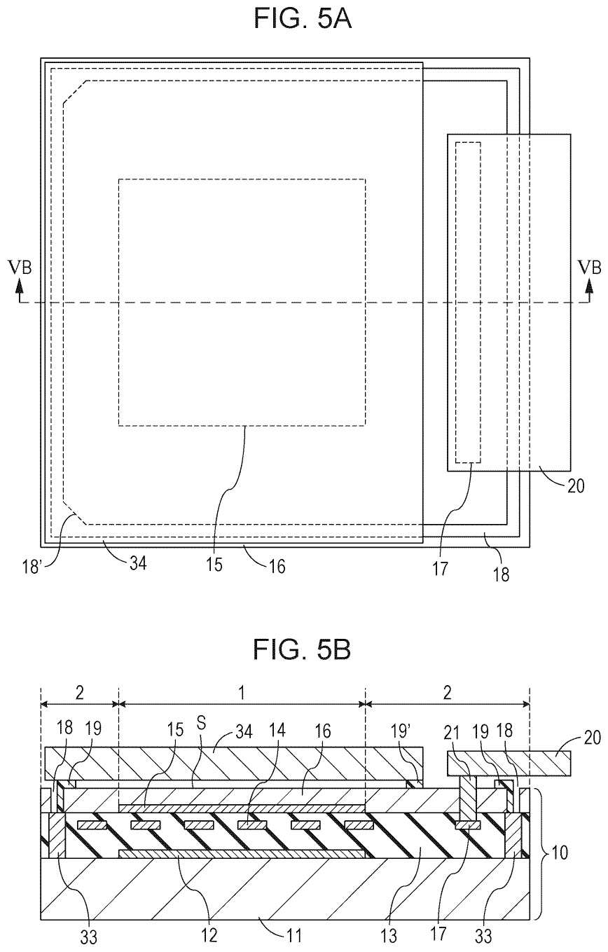

Another embodiment of the module will be described with reference to FIGS. 5A and 5B. The description of the configuration, functions, materials, advantageous effects, and the like, similar to those of the first embodiment is incorporated by reference without being repeated, for conciseness.

FIGS. 5A and 5B are schematic views illustrating the third embodiment of a module including an element substrate. FIG. 5A is a schematic plan view of the module relative to a surface S. FIG. 5B is a schematic cross-sectional view taken along the line VB-VB in FIG. 5A.

In the third embodiment, a second substrate 34 is bonded to the element substrate 10 via resin layers 19, 19′ so as to face the function element 15. The resin layer 19 is disposed so as to span at least part of the slit 18 provided in the insulating layer 16 even in a region that the second substrate 34 does not overlap. Because the second substrate 34 is bonded by the resin layer 19, no adhesive forming step is added for bonding the second substrate 34. When the second substrate 34 is bonded, the resin layer 19 spreads wider than the width at the time of application. However, the spread of the resin layer 19 does not extend beyond, i.e. is dammed by, the slit 18, thereby suppressing the overflow of the resin layer 19 from the edge of the element substrate 10. In other words, the slit 18 can be used for positioning the outer end of the adhesive. In a region where the slit 18 is not present, it is sufficient to dispose the resin layer 19′ made of the same material as the resin layer 19.

In the present embodiment, a guard ring 33 that penetrates the insulating layer 13 is disposed in the peripheral region 2 of the element substrate 10. The guard ring 33 is formed of a plurality of wiring layers, with via plugs and contact plugs connecting the wiring layers vertically to penetrate the insulating layer 13. The guard ring 33 is formed so as to penetrate the insulating layer 13. The guard ring 33 is provided to suppress the degradation of the element characteristics due to permeation of moisture, oxygen, and the like, from the edge of the element substrate 10 through the insulating layer 13 and reach of the moisture, oxygen, and the like, to the semiconductor element 12 and the function element 15.

In the present embodiment, the size of the peripheral region 2 is reduced by providing the slit 18 in the insulating layer 16 so as to overlap the guard ring 33 in a plan view, and to use the guard ring 33 as an etching stopper layer at the time of forming the slit 18 by etching.

In the present embodiment, inclined portions 18′ are provided at inner peripheral corners of the slit 18 in a plan view at the corner portions of the element substrate 10 in a region that the second substrate 34 overlaps. In other words, the width of the slit 18 at each of those corner portions of the element substrate 10 is wider than the width of the slit 18 other than those corner portions.

When the second substrate 34 is bonded to the element substrate 10 using the resin layer 19 as an adhesive, the resin layer 19 spreads wider than the width at the time of application. However, the pattern corner portions of the resin layer 19 may have a greater amount of application of the resin layer 19, so the spread width of the resin layer 19 tends to increase compared to straight portions. Therefore, the volume of the slit 18 at each of those corner portions is increased by providing the inclined portion 18′ at each of those inner peripheral corners of the slit 18, to further effectively suppress the extension of the resin layer 19 outside the slit 18 and the overflow of the resin layer 19 beyond the edge of the element substrate 10.

In FIGS. 5A and 5B, the same resin layer 19 is disposed in the slit 18 of the region that overlaps the second substrate 34 and the slit 18 of the region that does not overlap the second substrate 34. Alternatively, different resins may be used for the slits 18, respectively. For example, a material like a resin with a high adhesivity to the second substrate 34 or a resin containing spacer for space adjustment between the element substrate 10 and the second substrate 34 may be selected as the resin layer 19 for a region that overlaps the second substrate 34, and a potting resin for protecting the peripheral circuit region from static electricity or chemical substances or a protective resin that covers the upper side of the circuit substrate 20 to protect a joint between the element substrate 10 and the circuit substrate 20 may be formed as the resin layer 19 to span the slit 18 for a region that does not overlap the second substrate 34. When an ACF is used as the joining member 21 for the circuit substrate 20, forming the resin layer 19 before joining the circuit substrate 20 may cause a level difference of the resin layer 19 that affects the joining accuracy of the circuit substrate 20. On the other hand, after joining the circuit substrate 20, it is difficult to form the resin layer 19 because the circuit substrate 20 is disposed over the slit 18 so as to overlap the slit 18.

Therefore, by forming an ACF layer as the joining member 21 to span the slit 18, the ACF may also serve as the resin layer 19.

In the present embodiment, when the second substrate 34 is bonded so as to cover the slit 18, to further suppress the peeling of the insulating layer 16 from the slit 18 due to the application of external forces or impacts on the slit 18.

As described above, in the present embodiment as well, the peeling of the insulating layer 16 from the slit 18 is suppressed in a module assembly process.

### Fourth Embodiment

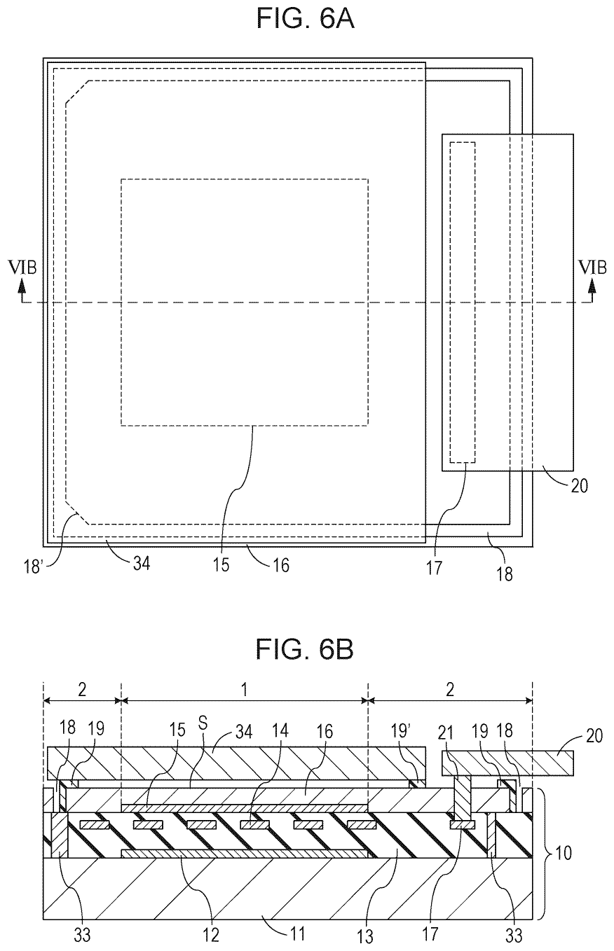

Another embodiment of the module will be described with reference to FIGS. 6A and 6B. The description of the configuration, functions, materials, advantageous effects, and the like, similar to those of the first to third embodiments is incorporated by reference without being repeated, for conciseness.

FIGS. 6A and 6B are schematic views illustrating the fourth embodiment of a module including an element substrate. FIG. 6A is a schematic plan view of the module relative to a surface S. FIG. 6B is a schematic cross-sectional view taken along the line VIB-VIB in FIG. 6A.

In the fourth embodiment, part of the slit 18 is disposed outside the guard ring 33 in a plan view. As in the case of the present embodiment, even when the slit 18 is disposed outside the guard ring 33, the peeling of the insulating layer 16 from the slit 18 due to the application of external forces or impacts on the slit 18 is suppressed.

According to the present disclosure, by providing a slit in an insulating layer, extension of the peeling of the insulating layer is suppressed during dicing of an element substrate, and disposing a resin layer in the slit of the insulating layer suppresses the peeling of the insulating layer from the slit during an assembly process, thereby improving yield.

<Organic Light Emitting Element and Apparatuses and Devices using the Element>

Next, embodiments of apparatuses and devices using the above-described element substrates will be described.

The element substrate of the present disclosure is suitably used in an organic light emitting apparatus equipped with organic light emitting elements.

The organic light emitting element includes a first electrode, a second electrode, and an organic compound layer disposed between these electrodes. One of the first electrode and the second electrode is an anode, and the other one of the first electrode and the second electrode is a cathode. In the organic light emitting element, the organic compound layer may be a single layer or may be a laminated body made up of a plurality of layers as long as the organic compound layer has a light emitting layer. Here, when the organic compound layer is a laminated body made up of a plurality of layers, the organic compound layer may include a hole injection layer, a hole transport layer, an electron blocking layer, a hole-exciton blocking layer, an electron transport layer, an electron injection layer, and the like, in addition to the light emitting layer. The light emitting layer may be a single layer or may be a laminated body made up of a plurality of layers. When the light emitting layer is made up of a plurality of layers, a charge generation layer may be provided between the light emitting layers. The charge generation layer may be composed of a compound having a lowest unoccupied molecular orbital energy (LUMO) lower than that of the hole transport layer, and the LUMO of the charge generation layer may be lower than the highest occupied molecular orbital energy (HOMO) of the hole transport layer. Here, the molecular orbital energy of the organic compound layer may be the energy level of the organic compound with the largest mass ratio in the organic compound layer.

Here, HOMO and LUMO are considered to be higher when the HOMO and the LUMO are closer to a vacuum level. The fact that the LUMO of the charge generation layer is lower than the HOMO of the hole transport layer means that the LUMO of the charge generation layer is closer to the vacuum level than the HOMO of the hole transport layer.

The HOMO and the LUMO can be calculated using molecular orbital calculations. Molecular orbital calculations are performed using density functional theory (DFT) or the like, and may be performed using B3LYP as a functional and using 6-31G* or the like as a basis function. Molecular orbital calculations can be performed using, for example, Gaussian09 (Gaussian09, Revision C.01, M. J. Frisch, G. W. Trucks, H. B. Schlegel, G. E. Scuseria, M. A. Robb, J. R. Cheeseman, G. Scalmani, V. Barone, B. Mennucci, G. A. Petersson, H. Nakatsuji, M. Caricato, X. Li, H. P. Hratchian, A. F. Izmaylov, J. Bloino, G. Zheng, J. L. Sonnenberg, M. Hada, M. Ehara, K. Toyota, R. Fukuda, J. Hasegawa, M. Ishida, T. Nakajima, Y. Honda, O. Kitao, H. Nakai, T. Vreven, J. A. Montgomery, Jr., J. E. Peralta, F. Ogliaro, M. Bearpark, J. J. Heyd, E. Brothers, K. N. Kudin, V. N. Staroverov, T. Keith, R. Kobayashi, J. Normand, K. Raghavachari, A. Rendell, J. C. Burant, S. S. Iyengar, J. Tomasi, M. Cossi, N. Rega, J. M. Millam, M. Klene, J. E. Knox, J. B. Cross, V. Bakken, C. Adamo, J. Jaramillo, R. Gomperts, R. E. Stratmann, O. Yazyev, A. J. Austin, R. Cammi, C. Pomelli, J. W. Ochterski, R. L. Martin, K. Morokuma, V. G. Zakrzewski, G. A. Voth, P. Salvador, J. J. Dannenberg, S. Dapprich, A. D. Daniels, O. Farkas, J. B. Foresman, J. V. Ortiz, J. Cioslowski, and D. J. Fox, Gaussian, Inc., Wallingford CT, 2010).

The HOMO and the LUMO can be calculated using the ionization potential and the band gap. The HOMO can be estimated by measuring the ionization potential. The ionization potential can be measured using a measuring instrument, such as AC-3, by dissolving a measurement target compound in a solvent, such as toluene. The band gap can be measured by dissolving a measurement target compound in a solvent, such as toluene, and applying excitation light to the solution. The band gap can be measured by measuring the absorption edge of the excitation light. Alternatively, the band gap can be measured by depositing a measurement target compound onto a substrate, such as glass, and applying excitation light to the deposited film. The band gap can be measured by measuring the absorption edge of the absorption spectrum that the deposited film absorbs.

The LUMO can be calculated using the values of the band gap and ionization potential. The LUMO can be estimated by subtracting the value of the ionization potential from the value of the band gap.

The LUMO can also be estimated from a reduction potential. For example, a one-electron reduction potential is estimated using cyclic voltammetry (CV) measurement. The CV measurement can be performed, for example, in a DMF solution of 0.1 M tetrabutylammonium perchlorate using an Ag/Ag⁺ as a reference electrode, Pt as a counter electrode, and glassy carbon as a working electrode. The LUMO can be estimated by adding the difference of the reduction potential of ferrocene relative to the reduction potential of the obtained compound to Δ4.8 eV.

In the organic light emitting element, the light emitting layer is, for example, a layer made of an organic metal complex or a layer made of an organic metal complex and another compound. When the light emitting layer is made of an organic metal complex and another compound, the organic metal complex may be used as a host of the light emitting layer or may be used as a guest of the light emitting layer. The organic metal complex may be used as an assist material that can be contained in the light emitting layer. Here, the host refers to a compound with the largest mass ratio among the compounds that compose the light emitting layer. The guest is a compound with a mass ratio smaller than the mass ratio of the host among the compounds that compose the light emitting layer and is a main compound responsible for light emission. The assist material is a compound with a mass ratio smaller than the mass ratio of the host among the compounds that compose the light emitting layer and is a compound that assists the light emission of the guest. The assist material is also referred to as a second host.

The host material can also be referred to as a first compound, and the assist material can also be referred to as a second compound.

When an organic metal complex is used as a guest of the light emitting layer, the concentration of the guest is higher than or equal to 0.01 mass % and lower than or equal to 20 mass %, and may be higher than or equal to 0.1 mass % and lower than or equal to 10 mass %. The guest is also called a dopant.

When an organic metal complex is used as a host or guest of the light emitting layer, particularly, as a guest of the light emitting layer, an element that exhibits high efficiency and high luminance light output with extremely high durability can be obtained. The light emitting layer may be a single layer or a multilayer, and the light emitting layer is also able to mix original emission colors by containing light emitting materials that have other emission colors. A multilayer means a state where a light emitting layer and another light emitting layer are laminated. In this case, the emission color of the organic light emitting element is not limited to red, blue, or green. More specifically, the emission color may be white or an intermediate color. In the case of white, a plurality of light emitting layers respectively produce red, blue, and green light.

### <Film Formation Method as Vapor Deposition or Application>

Organic metal complexes can be used as constituent materials of organic compound layers other than the light emitting layer.

Specifically, organic metal complexes may be used as constituent materials of an electron transport layer, an electron injection layer, a hole transport layer, a hole injection layer, a hole blocking layer, and the like. In this case, the emission color of the organic light emitting element is not limited to red, blue, or green. More specifically, the emission color may be a white emission color or an intermediate color.

Here, other than organic metal complexes, generally known low-molecular and polymer hole injection compounds, hole transport compounds, host compounds, light emitting compounds, electron injection compounds, electron transport compounds, or the like, may be used together.

Hole injection and transport materials can have high hole mobility, which facilitate the injection of holes from the anode and can transport the injected holes to the light emitting layer. In order to reduce the degradation of film quality, such as crystallization, in the organic light emitting element, materials with a high glass transition temperature can be used. Low-molecular and polymer materials with hole injection transport capabilities include triarylamine derivatives, aryl carbazole derivatives, phenylenediamine derivatives, stilbene derivatives, phthalocyanine derivatives, porphyrin derivatives, poly(vinyl carbazole), poly(thiophene), and other conductive polymers. The hole injection and transport materials are also suitably used for electron blocking layers.

Light emitting materials mainly related to light emitting functions include fused ring compounds (such as fluorene derivatives, naphthalene derivatives, pyrene derivatives, perylene derivatives, tetracene derivatives, anthracene derivatives, and rubrene), quinacridone derivatives, coumarin derivatives, stilbene derivatives, organic aluminum complexes such as tris(8-quinolinolato)aluminum, iridium complexes, platinum complexes, rhenium complexes, copper complexes, europium complexes, ruthenium complexes, and polymer derivatives such as poly(phenylene vinylene) derivatives, poly(fluorene) derivatives, and poly(phenylene) derivatives.

When the light emitting material is a hydrocarbon compound, a decrease in luminous efficiency due to exciplex formation and a decrease in color purity due to changes in the emission spectrum of the light emitting material caused by exciplex formation can be reduced.

When the light emitting material is a fused polycyclic compound including a five-membered ring, the light emitting material has a high ionization potential, so the light emitting material can be difficult to oxidize and can result in an element with a highly durable life.

Examples of light emitting layer hosts or light emission assisting materials contained in the light emitting layers include aromatic hydrocarbon compounds or their derivatives, carbazole derivatives, dibenzofuran derivatives, dibenzothiophene derivatives, organic aluminum complexes, such as tris(8-quinolinolato)aluminum, and organic beryllium complexes.

Electron transport materials can be freely selected from those that can transport electrons injected from the cathode to the light emitting layer, and are selected in consideration of, for example, the balance with the hole mobility of the hole transport material. Materials with electronic transport capabilities include oxadiazole derivatives, oxazole derivatives, pyrazine derivatives, triazole derivatives, triazine derivatives, quinoline derivatives, quinoxaline derivatives, phenanthroline derivatives, organic aluminum complexes, and fused ring compounds (such as fluorene derivatives, naphthalene derivatives, chrysene derivatives, and anthracene derivatives). The electron transport materials are also suitably used in hole blocking layers.

Electron injection materials can be freely selected from those that can easily inject electrons from the cathode, and are selected in consideration of, for example, the balance with hole injection properties. Organic compounds also include n-type dopants and reducing dopants. Examples of the n-type dopants and reducing dopants include compounds including an alkali metal such as a lithium fluoride, a lithium complex such as lithium quinolinolate, a benzimidazolylidene derivative, an imidazolylidene derivative, a fulvalene derivative, and an acridine derivative.

The electron injection materials can also be used in conjunction with the electron transport materials.

The organic light emitting element is provided such that an insulating layer, a first electrode, an organic compound layer, and a second electrode are formed on a substrate. A protective layer, a color filter, a microlens, or the like may be provided on the second electrode. When the color filter is provided, a planarization layer may be provided between the color filter and the protective layer. The planarization layer may be made of acrylic resin or the like. This also applies to a case where the planarization layer is provided between the color filter and the microlens. The constituent members will be described below.

### <Substrate>

Examples of the substrate include quartz, glass, silicon wafer, resin, and metal. Switching elements, such as transistors, and wires may be provided on the substrate, and an insulating layer may be further provided thereon. The insulating layer may be made of any material as long as a contact hole can be formed such that a wire can be formed between the insulating layer and the first electrode and insulation from a non-connected wire can be ensured. The insulating layer may be, for example, a resin, such as polyimide, silicon oxide, silicon nitride, or the like.

### <Electrodes>

A pair of electrodes may be used as electrodes. The pair of electrodes may be an anode and a cathode.

When an electric field is applied in a direction in which the organic light emitting element emits light, the electrode having a higher potential is an anode, and the other electrode is a cathode. In other words, the electrode that supplies holes to a light emitting layer is an anode, and the electrode that supplies electrons is a cathode.

A constituent material of the anode can be the one with a work function that is as large as possible. For example, a metal chemical element, such as gold, platinum, silver, copper, nickel, palladium, cobalt, selenium, vanadium, and tungsten, a mixture containing one or some of these metal chemical elements, an alloy made of a combination of some of these metal chemical elements, or a metal oxide, such as a tin oxide, a zinc oxide, an indium oxide, ITO, and an indium zinc oxide, may be used. A conductive polymer, such as polyaniline, polypyrrole, and polythiophene, may be used.

One type of these electrode materials may be used solely or two or more types of these electrode materials may be used together. The anode may be one layer or may be a plurality of layers.

When the anode is used as a reflecting electrode, for example, chromium, aluminum, silver, titanium, tungsten, molybdenum, an alloy of some of these materials, a laminate of some of these materials, or the like may be used. The above materials may be used to function as a reflective film that does not serve as an electrode. When the anode is used as a transparent electrode, a transparent conductive oxide layer, such as ITO and indium zinc oxide, or the like, may be used; however, the material is not limited thereto.

Photolithography may be used to form electrodes.

On the other hand, the constituent material of the cathode can be the one with a small work function. Examples of the constituent material of the cathode include alkali metals, such as lithium, alkaline earth metals, such as calcium, metal chemical elements, such as aluminum, titanium, manganese, silver, lead, and chromium, and mixtures containing one or some of these metal chemical elements. Alternatively, an alloy made of a combination of some of these metal chemical elements may be used. For example, magnesium-silver, aluminum-lithium, aluminum-magnesium, silver-copper, zinc-silver, or the like may be used. A metal oxide, such as ITO, may also be used. One type of these electrode materials may be used solely or two or more types of these electrode materials may be used together. The cathode may be a single layer or may be a plurality of layers. Among others, silver can be used, and a silver alloy can be further used to reduce aggregation of silver. As long as aggregation of silver is reduced, the ratio of an alloy does not matter. For example, the ratio of silver to another metal may be one to one, three to one, or the like.

A cathode may be made as a top emission element by using an oxide conductive layer made of ITO or the like or may be made as a bottom emission element by using a reflecting electrode made of aluminum (Al) or the like. The arrangement of the cathode is not limited. A method of forming a cathode is not limited. When a direct-current and alternating-current sputtering method or the like is used, the film has a good coverage, and reduces the resistance.

### <Pixel Define Layer>

A pixel define layer is made up of a silicon nitride (SiN) film, a silicon oxynitride (SiON) film, or a silicon oxide (SiO) film formed with a chemical vapor deposition method (CVD method).

To increase the resistance in an in-plane direction of an organic compound layer, the film thickness of the organic compound layer, particularly, the hole transport layer can be thinly formed at a side wall of the pixel define layer. Specifically, an eclipse during vapor deposition is increased by increasing a taper angle of a side wall of the pixel define layer or increasing the film thickness of the pixel define layer, with the result that the film thickness of the side wall can be made thin.

On the other hand, the side wall taper angle of the pixel define layer or the film thickness of the pixel define layer can be adjusted to such an extent that no air gap is formed in the protective layer formed on the pixel define layer. Since no air gap is formed in the protective layer, the occurrence of defects in the protective layer is reduced. Since occurrence of defects in the protective layer is reduced, reliability may be increased, such as occurrence of a dark spot and occurrence of poor conduction of the second electrode.

### <Organic Compound Layer>

An organic compound layer may be a single layer or may be a plurality of layers. When the organic compound layer has a plurality of layers, the layers are called a hole injection layer, a hole transport layer, an electron blocking layer, a light emitting layer, a hole blocking layer, an electron transport layer, and an electron injection layer, depending on their functions. The organic compound layer is mainly made of an organic compound. However, the organic layer may include inorganic atoms and inorganic compounds. The organic layer 4 may include, for example, copper, lithium, magnesium, aluminum, iridium, platinum, molybdenum, and zinc. The organic compound layer may be disposed between the first electrode and the second electrode and may be disposed in contact with the first electrode and the second electrode.

When a plurality of light emitting layers is provided, a charge generation portion may be provided between a first light emitting layer and a second light emitting layer. The charge generation portion may have an organic compound with a LUMO of −5.0 eV or lower. The same applies when a charge generation portion is provided between the second light emitting layer and a third light emitting layer.

The organic compound layers (a hole injection layer, a hole transport layer, an electron blocking layer, a light emitting layer, a hole blocking layer, an electron transport layer, an electron injection layer, and the like) that constitute the organic light emitting element are formed by a method described below.

The organic compound layer can be formed by using a dry process, such as a vacuum evaporation method, an ionized evaporation method, sputtering, and plasma. Instead of the dry process, a wet process in which an organic compound is dissolved in an appropriate solvent and a layer is formed by using a known coating method (such as spin coating, dipping, a casting method, an LB method, and an ink-jet method) may be used.

When a layer is formed by using a vacuum evaporation method, a solution coating method, or the like, crystallization or the like is less likely to occur, and it is excellent in temporal stability. When a film is formed by using a coating method, the film can be formed in combination with an appropriate binder resin.

Examples of the binder resin include polyvinyl carbazole resin, polycarbonate resin, polyester resin, ABS resin, acrylic resin, polyimide resin, phenolic resin, epoxy resin, silicone resin, and urea resin; however, the binder resin is not limited to these materials.

One type of these binder resins may be used solely as a homopolymer or a copolymer or two or more types of these binder resins may be blended and used. An additive, such as a known plasticizer, a known oxidation inhibitor, and a known ultraviolet absorbent, may be used together.

### <Protective Layer>

A protective layer may be provided on the second electrode. For example, when glass provided with a humectant is bonded onto the second electrode, entry of water or the like to the organic compound layer is reduced, thereby improving the display. In another embodiment, a passivation film made of silicon nitride or the like may be provided on a cathode to reduce entry of water or the like to the organic compound layer. For example, the protective layer may be provided by conveying the cathode after being formed to another chamber without breaking a vacuum and forming a 2-μm-thick silicon nitride film by CVD. After deposition with CVD, a protective layer using atomic layer deposition (ALD) may be provided. The material of the film formed by ALD is not limited and may be a silicon nitride, a silicon oxide, an aluminum oxide, or the like. A silicon nitride may be formed by CVD further on the film formed by ALD. The film thickness of the film formed by ALD may be less than the film thickness of the film formed by CVD. Specifically, the film thickness of the film formed by ALD may be less than or equal to 50% of the film thickness of the film formed by CVD and, may be less than or equal to 10% of the film thickness of the film formed by CVD.

### <Color Filter>

A color filter may be provided on the protective layer. For example, a color filter designed in consideration of the size of the organic light emitting element may be provided on another substrate, and the substrate may be bonded to a substrate on which the organic light emitting element is provided. Alternatively, a color filter may be patterned on the above-described protective layer by using photolithography. A color filter may be made of a polymer.

### <Planarization Layer>

A planarization layer may be provided between the color filter and the protective layer. The planarization layer is provided for the purpose of reducing the irregularities of the lower layer. The planarization layer may be called a resin material layer without limiting the purpose. The planarization layer may be made of an organic compound and may be a low-molecular compound or a polymer compound. The planarization layer can be a polymer.

The planarization layer may be provided on the upper and lower sides of the color filter, and the constituent materials of those layers may be the same or may be different. Specifically, the planarization layer may be polyvinyl carbazole resin, polycarbonate resin, polyester resin, ABS resin, acrylic resin, polyimide resin, phenolic resin, epoxy resin, silicone resin, urea resin, or the like.

### <Microlens>

The organic light emitting element may include an optical member, such as a microlens, on its light emission side. The microlens can be made of acrylic resin, epoxy resin, or the like. The microlens may be provided for the purpose of increasing the amount of light extracted from the organic light emitting element and controlling the direction in which light is extracted. The microlens may have a hemispherical shape. When the microlens has a hemispherical shape, there is a tangent parallel to the insulating layer among tangents that touch the hemisphere, and the contact between the parallel tangent and the hemisphere is the vertex of the microlens. The vertex of the microlens can be similarly determined even in a selected sectional view. In other words, there is a tangent parallel to the insulating layer among tangents that touch the semicircle of the microlens in the sectional view, and the contact between the parallel tangent and the semicircle is the vertex of the microlens.

The middle point of the microlens can be defined. In the cross section of the microlens, a line segment from a point at which the shape of a circular arc ends to another point at which the shape of the circular arc ends is imagined, and the middle point of the line segment can be called the middle point of the microlens. A cross section to determine a vertex or a middle point may be a cross section perpendicular to the insulating layer.

The microlens has a first surface having a convex portion and a second surface on the opposite side from the first surface. The second surface can be disposed closer to the functional layer than the first surface. To provide such a configuration, the microlenses need to be formed on the light emitting apparatus. When the functional layer is an organic layer, a process accompanied by high temperature can be avoided in a manufacturing process. When the second surface is disposed closer to the functional layer than the first surface, all the glass transition temperatures of the organic compounds that make up the organic layer are higher than or equal to 100° C. and may be higher than or equal to 130° C.

### <Counter Substrate>

A counter substrate may be provided on the planarization layer. The counter substrate is provided at a position corresponding to the above-described substrate. The constituent material of the counter substrate may be the same as that of the above-described substrate. When the above-described substrate is a first substrate, the counter substrate may be a second substrate.

### <Pixel Circuit>

The light emitting apparatus having organic light emitting elements may include pixel circuits connected to the light emitting elements. The pixel circuits may be of an active matrix type that independently controls a first light emitting element and a second light emitting element. The active-matrix circuits may operate in accordance with voltage programming or current programming. A drive circuit includes the pixel circuit for each pixel. Each of the pixel circuits may include the light emitting element, a transistor that controls the emission luminance of the light emitting element, a transistor that controls light emission timing, a capacitor that holds the gate voltage of the transistor that controls the emission luminance, and a transistor for connection with a ground (GND) without intervening the light emitting element.

The light emitting apparatus may include a display region and a peripheral region disposed around the display region. The display region includes the pixel circuits, and the peripheral region includes a display control circuit. The mobility of the transistor that is a component of the pixel circuit may be smaller than the mobility of a transistor that is a component of the display control circuit.

The slope of the current-voltage characteristics of the transistor that is a component of the pixel circuit may be smaller than the slope of the current-voltage characteristics of the transistor that is a component of the display control circuit. The slope of the current-voltage characteristics can be measured in accordance with so-called Vg-Ig characteristics.

The transistor that is a component of the pixel circuit is a transistor connected to the light emitting element, such as a first light emitting element.

### <Pixel>

The organic light emitting apparatus includes the plurality of pixels. Each pixel has sub-pixels that produce light in different colors from each other. The sub-pixels may respectively have, for example, RGB emission colors.

The region of the pixel called a pixel aperture produces light. This region is the same as a first region.

The pixel aperture may be less than or equal to 15 μm and may be greater than or equal to 5 μm. More specifically, the pixel aperture may be 11 μm, 9.5 μm, 7.4 μm, 6.4 μm, or the like.

The spacing between the sub-pixels may be less than or equal to 10 μm and, specifically, may be 8 μm, 7.4 μm, or 6.4 μm.

The pixels can take known arrangement patterns in a plan view. The pixels may be arranged in, for example, a stripe pattern, a delta pattern, a PenTile® pattern, or a Bayer pattern. The shape of each sub-pixel in a plan view may be any one of known shapes. The shape of each sub-pixel in a plan view is, for example, a quadrangular shape, such as a rectangular shape and a rhombic shape, or a hexagonal shape. Of course, when the shape is not an exact shape but is close to a rectangular shape, the shape is considered to be included in a rectangular shape. The shape of each sub-pixel and the pixel array may be used in combination.

### <Uses of Organic Light Emitting Element>

The organic light emitting element can be used as a constituent member of a display apparatus or a constituent member of an illumination apparatus. There are other uses, such as an exposure light source of an electrophotographic image forming apparatus and a light emitting apparatus including color filters for a backlight or white light source of a liquid crystal display apparatus.

A display apparatus may be an image information processing apparatus. The image information processing apparatus includes an image input unit that enters image information from an area charge-coupled device (CCD), a linear CCD, a memory card, or the like, and an information processing unit that processes input information. The image information processing apparatus displays the input image on a display unit.

A display unit of an image capturing apparatus or ink-jet printer may have a touch panel function. A drive system of the touch panel function may be an infrared radiation method, a capacitance method, a resistive film method, or an electromagnetic induction method and is not limited. A display apparatus may be used as a display unit of a multifunction printer.

Next, a display apparatus will be described with reference to the attached drawings.

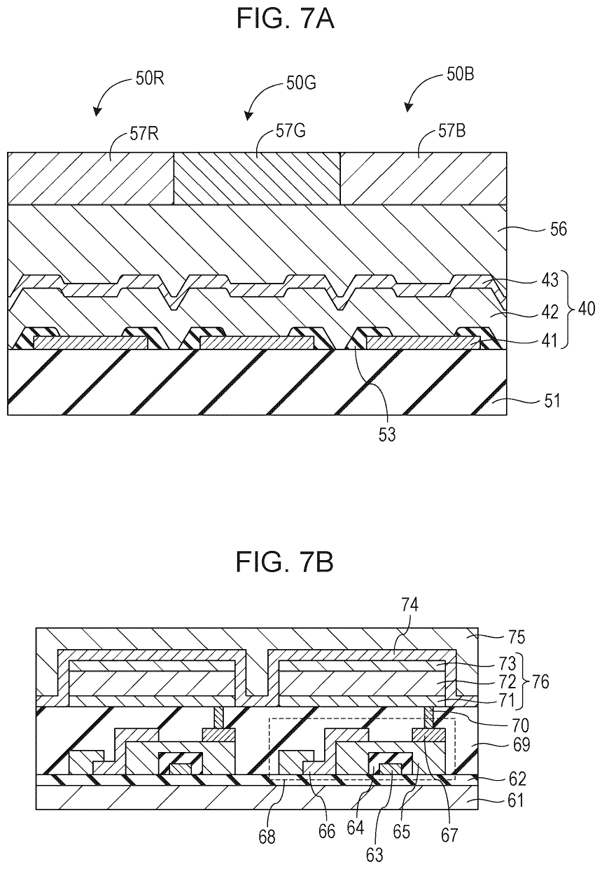

FIGS. 7A and 7B are schematic cross-sectional views that show an example of a display apparatus that includes an organic light emitting element and a transistor connected to the organic light emitting element. The transistor is an example of an active element. The transistor may be a thin film transistor (TFT).

FIG. 7A is an example of a pixel, which is a component of the display apparatus. The pixel includes sub-pixels 50R, 50G, and 50B, according to the light emission. An emission color may be distinguished by the wavelength of light emitted from the light emitting layer, or the light emitted from the sub-pixel may undergo selective transmission or color conversion by the color filter or the like. Each sub-pixel includes a first electrode 41 that is a reflecting electrode on the interlayer insulating layer 51, an insulating layer 53 that covers the edge of the first electrode 41, an organic compound layer 42 that covers both the first electrode 41 and the insulating layer 53, a transparent electrode as a second electrode 43, a protective layer 56, and a respective color filter 57R, 57G, 57B, according to color.

A transistor and a capacitive element are disposed beneath or within the interlayer insulating layer 51. The transistor and the first electrode 41 are electrically connected via a contact hole or the like.

The insulating layer 53 is also called a bank or a pixel define layer, covers the edge of the first electrode 41, and is disposed so as to surround the first electrode 41. A part where the insulating layer 53 is not disposed contacts with the organic compound layer 42 and serves as a light emitting region. The organic light emitting element 40 is composed of the first electrode 41, the organic compound layer 42, and the second electrode 43.

The second electrode 43 may be a transparent electrode, a reflecting electrode, or a semi-transparent electrode.

The protective layer 56 reduces penetration of moisture into the organic compound layer 42. Although illustrated as one layer, the protective layer 56 may be formed as a plurality of layers. An inorganic compound layer or an organic compound layer may be provided for each layer.

The color filters 57R, 57G, and 57B may be formed on a planarizing film. A resin protective layer may be provided on the color filters. The color filters 57R, 57G, and 57B may be formed on the protective layer 56. Alternatively, the color filters 57R, 57G, and 57B may be provided on a counter substrate, such as a glass substrate, and then bonded.

The display apparatus of FIG. 7B includes organic light emitting elements 76 and TFTs 68, as examples of the transistor. The display apparatus includes a substrate 61 made of glass, silicon, or the like, and an insulating layer 62 provided on top of the substrate 61. The active element 68, such as a TFT, is disposed on the insulating layer 62. A gate electrode 63, a gate insulating film 64, and a semiconductor layer 65 of the active element 68 are disposed on the insulating layer 62. The TFT 68 may include the semiconductor layer 65, a drain electrode 66, and a source electrode 67. An insulating film 69 is provided on top of the TFT 68. An anode 71 that constitutes the organic light emitting element 76 is connected to the source electrode 67 via a contact hole 70 provided in the insulating film 69.

The method of electrical connection between the electrodes (anode, cathode) included in the organic light emitting element 76 and the electrodes (source electrode, drain electrode) included in the TFT is not limited to the method shown in FIG. 7B. In other words, it is sufficient for any one of the anode and the cathode to be electrically connected to any one of the TFT source electrode and the TFT drain electrode.

In the display apparatus of FIG. 7B, the organic compound layer 72 is illustrated as a single layer. However, the organic compound layer 72 may be made up of a plurality of layers. A first protective layer 74 and a second protective layer 75 are provided on the cathode 73 to reduce degradation of the organic light emitting element 76.

In the display apparatus of FIG. 7B, a transistor is used as a switching element. Alternatively, other switching elements may be used instead.

The transistors used in the display apparatus shown in FIG. 7B are not limited to transistors using single crystalline silicon wafers. The transistors may be thin-film transistors that have an active layer on an insulating surface of the substrate. Examples of the active layer include single crystalline silicons, non-single crystalline silicons, such as amorphous silicon and microcrystalline silicon, and non-single crystalline oxide semiconductors, such as indium zinc oxide and indium gallium zinc oxide. Thin-film transistors are also called TFT elements.

The transistors included in the display apparatus of FIG. 7B may be formed within a substrate, such as an Si substrate. The phrase formed within a substrate means that a transistor is manufactured by processing a substrate, such as an Si substrate, itself. In other words, having a transistor within a substrate may also indicate that a substrate and a transistor are integrally formed.

The emission luminance of the organic light emitting element according to the present embodiment is controlled by a TFT that is an example of a switching element. When a plurality of organic light emitting elements is provided within the same plane, images may be displayed using their respective emission luminances. The switching element according to the present embodiment is not limited to a TFT and may be a transistor formed of low-temperature polysilicon or an active matrix driver formed on a substrate, such as an Si substrate. The phrase on a substrate may also refer to within the substrate.

Whether to provide a transistor within a substrate or use a TFT is selected based on the size of a display unit. When, for example, the size is around 0.5 inches, an organic light emitting element can be provided on an Si substrate.

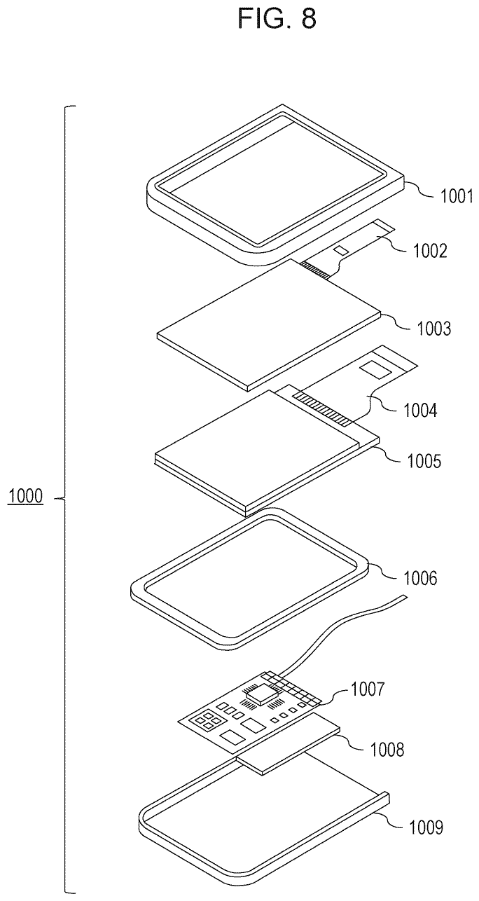

FIG. 8 is a schematic exploded perspective view that shows an example of a display apparatus. The display apparatus 1000 includes a touch panel 1003, a display panel 1005, a frame 1006, a circuit substrate 1007, and a battery 1008 between a top cover 1001 and a bottom cover 1009. An FPC 1002 is connected to the touch panel 1003. Another FPC 1004 is connected to the display panel 1005. Transistors are printed on the circuit substrate 1007. The battery 1008 does not need to be provided when the display apparatus is not a mobile device, or may be provided at another position even when the display apparatus is a mobile device.

The display apparatus according to the present embodiment may include red, green, and blue color filters. The red, green, and blue color filters may be arranged in a delta pattern.

The display apparatus according to the present embodiment may be used in a display unit of a mobile terminal. In this case, the display apparatus may have a display function and an operating function. Examples of the mobile terminal include a cellular phone such as a smartphone, a tablet, and a head mounted display.

The display apparatus according to the present embodiment may be used in a display unit of an image pickup apparatus including an optical unit having a plurality of lenses and an image pickup element that receives light passing through the optical unit. The image capturing apparatus may include a display unit that displays information acquired by the image pickup element. The display unit may be exposed to the outside of the image capturing apparatus or may be disposed in a viewfinder.

The image capturing apparatus may be a digital camera or a digital camcorder.

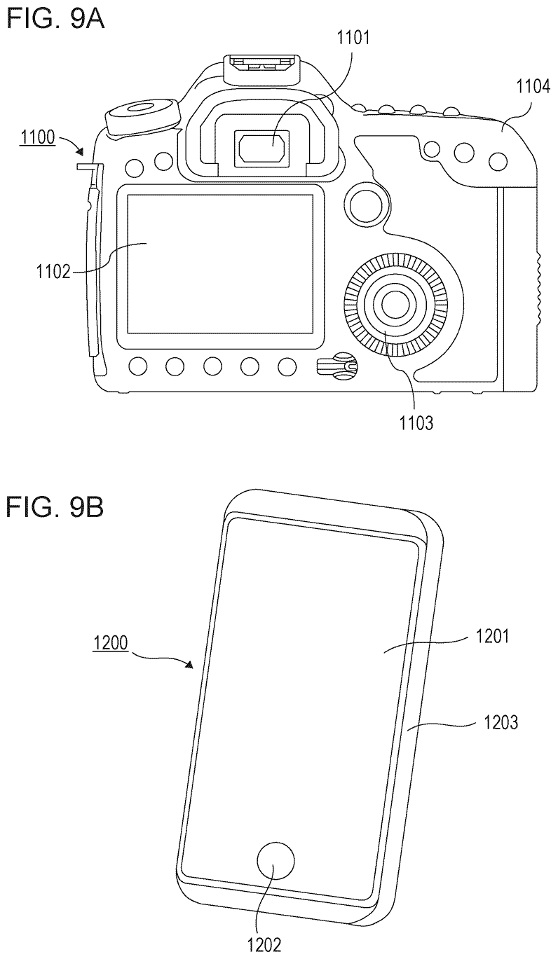

FIG. 9A is a schematic view that shows an example of an image capturing apparatus according to an embodiment. The image capturing apparatus 1100 includes a viewfinder 1101, a back display 1102, an operating portion 1103, and a housing 1104. The viewfinder 1101 includes the display apparatus according to the above-described embodiment. In this case, the display apparatus may display not only an image to be captured but also environmental information, an image capturing instruction, and the like. The environmental information may include the intensity of external light, the direction of external light, the moving speed of a subject, a possibility that a subject is shielded by a shielding material, or the like.

Since suitable timing for image capturing is a small amount of time, information is displayed as early as possible. Therefore, a display apparatus that uses an organic light emitting element with a high response speed can be adopted. The display apparatus using organic light emitting elements is more suitably used than a liquid crystal display apparatus for these apparatuses, and provides higher display speed.

The image capturing apparatus 1100 includes an optical unit. The optical unit has a plurality of lenses and forms an image on the image pickup element accommodated in the housing 1104. The plurality of lenses are capable of adjusting a focal point by adjusting the relative positions of the lenses. This operation can be automatically performed. The image capturing apparatus may be referred to as a photoelectric conversion apparatus. The photoelectric conversion apparatus can sequentially capture an image and can include a method a method of detecting a difference from a previous image, a method of extracting an image from an image being constantly recorded, or the like, as a method of capturing an image.

FIG. 9B is a schematic view that shows an example of an electronic device. The electronic device 1200 includes a display unit 1201, an operating portion 1202, and a housing 1203. The housing 1203 may contain a circuit, a printed circuit board having the circuit, a battery, and a communication unit. The operating portion 1202 may be formed as a button or may be provided as a touch panel-type response unit. The operating portion 1202 may be a biometric authentication unit that identifies a fingerprint to, for example, release a lock. The electronic device 1200 including the communication unit may be regarded as a communication device. The electronic device 1200 may provide a camera function by including a lens and an image pickup element. An image captured by the camera function may be displayed on the display unit 1201. The electronic device 1200 may be a smartphone, a notebook computer, or the like.

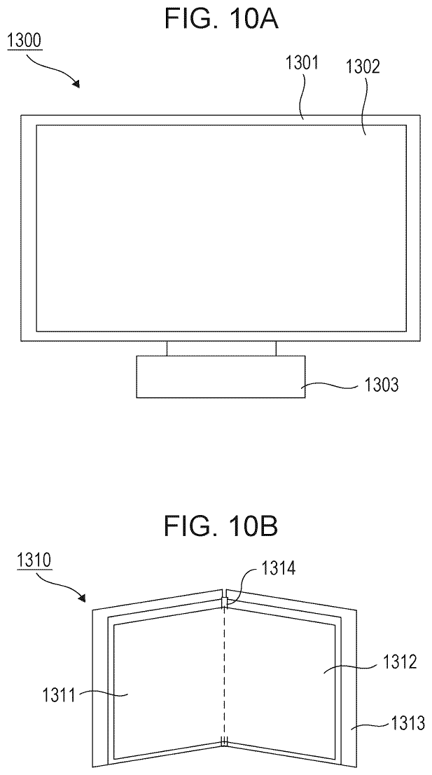

FIGS. 10A and 10B are schematic views that show examples of a display apparatus. FIG. 10A is a display apparatus, such as a television monitor and a PC monitor. The display apparatus 1300 includes a frame 1301 and a display unit 1302. The organic light emitting elements are used in the display unit 1302.

The display apparatus 1300 includes a base 1303 that supports the frame 1301 and the display unit 1302. The base 1303 is not limited to the mode of FIG. 10A. The bottom side of the frame 1301 may serve as a base.

The frame 1301 and the display unit 1302 may be curved. The radius of curvature may be greater than or equal to 5000 mm and less than or equal to 6000 mm.

A display apparatus 1310 of FIG. 10B is configured to be foldable, and is a so-called foldable display apparatus. The display apparatus 1310 includes a first display unit 1311, a second display unit 1312, a housing 1313, and a folding point 1314. The first display unit 1311 and the second display unit 1312 have a light emitting apparatus using organic light emitting elements. The first display unit 1311 and the second display unit 1312 may form a seamless one-sheet display apparatus. The first display unit 1311 and the second display unit 1312 may be separated at the folding point 1314. The first display unit 1311 and the second display unit 1312 may respectively display different images or the first and second display units 1311, 1312 may display one image.

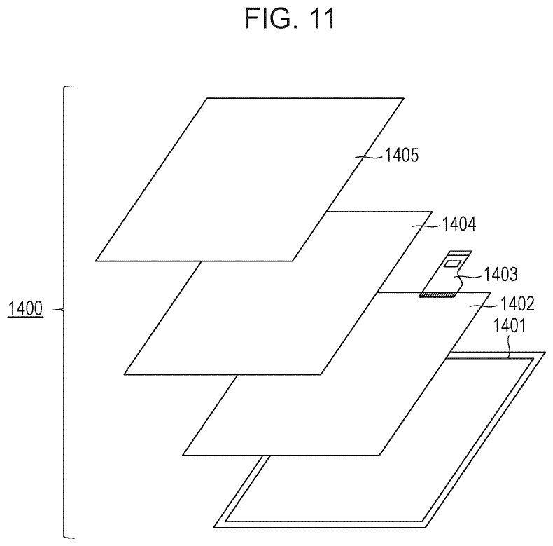

FIG. 11 is a schematic exploded perspective view that shows an example of an illumination apparatus. The illumination apparatus 1400 includes a housing 1401, a light source 1402, a circuit substrate 1403, an optical film 1404, and a light diffusion unit 1405. The light source 1402 includes an organic light emitting element. The optical film 1404 may be a filter that improves the color rendering property of the light source 1402. The light diffusion unit 1405 is capable of diffusing light from the light source 1402 for illumination or the like, to broaden the range of the light. The optical film 1404 and the light diffusion unit 1405 may be provided on a light emission side of illumination, and a cover may be provided at the outermost part.

The illumination apparatus 1400 provides illumination, for example, illumination of a room. The illumination apparatus 1400 may produce light in any one of white color, daylight color, and other colors from blue to red. The illumination apparatus 1400 may include a light modulating circuit that modulates light of any of those colors. The illumination apparatus 1400 includes an organic light emitting element and a power supply circuit connected to the organic light emitting element. The power supply circuit converts alternating-current voltage to direct-current voltage. White has a color temperature of 4200K, and daylight color has a color temperature of 5000K. The illumination apparatus 1400 may include a color filter.

The illumination apparatus 1400 according to the present embodiment may include a heat radiation portion. The heat radiation portion emits heat from inside the apparatus to the outside of the apparatus and may be made of a metal having a high specific heat, liquid silicone, or the like.

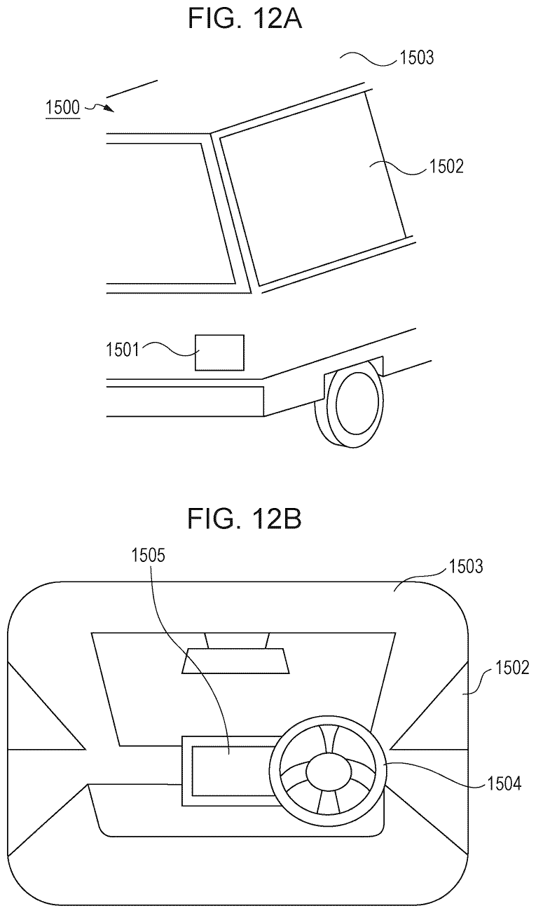

FIGS. 12A and 12B are schematic views of an automobile that is an example of a moving object. The automobile includes a tail lamp that is an example of a lamp. The automobile 1500 includes the tail lamp 1501 and may be configured to, when brake operation or the like is performed, turn on the tail lamp 1501.

The tail lamp 1501 includes an organic light emitting element. The tail lamp 1501 may include a protective member that protects the organic light emitting element. The protective member may be made of any material as long as the protective member has a high strength to a certain extent and can be made of polycarbonate or the like. A furan dicarboxylic acid derivative, an acrylonitrile derivative, or the like may be mixed with polycarbonate.

The automobile 1500 may include a body 1503 and windows 1502 fixed to the body 1503. The windows 1502 other than windows for viewing the front and rear of the automobile 1500 each may be a transparent display. The transparent display is the display apparatus of the above-described embodiment. In this case, the constituent materials of the electrodes and the like of each organic light emitting element are made up of transparent members.

As shown in FIG. 12B, the automobile 1500 includes a steering wheel 1504 used to control the moving direction of the moving object, a display unit 1505 that is mounted on the vehicle body 1503 and that shows a map, the position of the moving object, the direction to turn, and the like. The display unit 1505 includes the display apparatus of the above-described embodiment.

The moving object according to the present embodiment includes one or both of a driving force generation unit that mainly generates the driving force used to move the moving object and a rotating member that is mainly used to move the moving object. The driving force generation unit can be an engine, a motor, or the like. The rotating member can be a tire, a wheel, a screw of a ship, a propeller of a flight vehicle, or the like. Specifically, the moving object may be a bicycle, an automobile, a train, a ship, an airplane, a drone, or the like. The moving object may include a body and a lamp provided on the body or a display unit provided on the body. The lamp may be equipped with lighting to inform the position of the body, and the display unit may have organic light emitting elements.

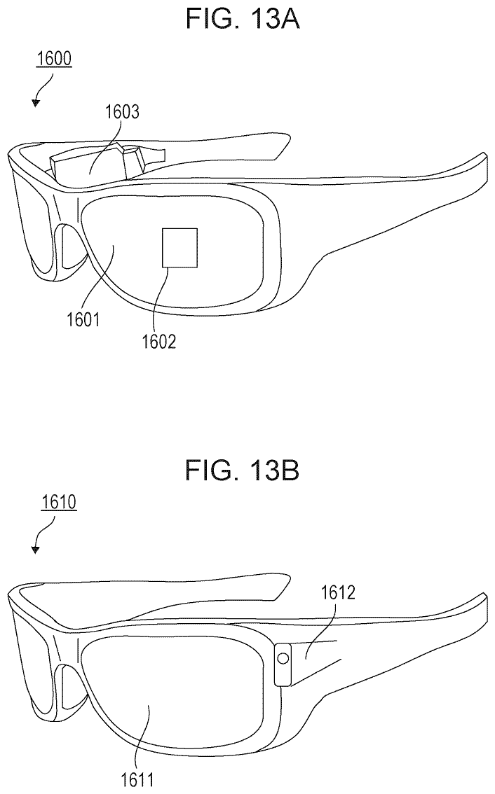

Application examples of the display apparatus of each of the above-described embodiments will be described with reference to FIGS. 13A and 13B. The display apparatus is applicable to a wearable system as a wearable device, such as smart glasses, an HMD, and a smart contact lens. An image capturing and display apparatus used in such application examples includes an image capturing apparatus capable of performing photoelectric conversion of visible light and a display apparatus capable of producing visible light.

FIG. 13A is a schematic view of glasses 1600 (smart glasses) according to one application example. An image capturing apparatus 1602, such as a CMOS sensor and an SPAD, is provided on the front side of a lens 1601 of the glasses 1600. The display apparatus of any one of the above-described embodiments is provided on the back side of the lens 1601.

The glasses 1600 further include a controller 1603. The controller 1603 functions as a power supply to supply electric power to the image capturing apparatus 1602 and the display apparatus according to any one of the embodiments. The controller 1603 controls the operations of the image capturing apparatus 1602 and the display apparatus. An optical system for condensing light to the image capturing apparatus 1602 is formed in the lens 1601.

FIG. 13B is a schematic view of glasses 1610 (smart glasses) according to another application example.

The glasses 1610 include a controller 1612. An image capturing apparatus, corresponding to the image capturing apparatus 1602, and the display apparatus are mounted on the controller 1612. An optical system for projecting light emitted from the display apparatus in the controller 1612 is formed in a lens 1611, and an image is projected onto the lens 1611. The controller 1612 functions as a power supply to supply electric power to the image capturing apparatus and the display apparatus and also controls the operations of the image capturing apparatus and the display apparatus. The controller 1612 may include a gaze detection unit that detects the gaze of a wearer. Gaze detection may use infrared light. An infrared emitting unit emits infrared light to the eye of a user gazing at a display image. Infrared light emitted and reflected from the eye is detected by an image capturing unit including a light receiving element. Thus, a captured image of the eye is obtained. A reducer that reduces light from the infrared emitting unit to the display unit in a plan view is provided, so a decrease in image quality is reduced.

The gaze of the user toward the display image is detected from the captured image of the eye, obtained through image capturing with infrared light. A selected known technique may be applied to gaze detection using a captured image of eye. In an example, a gaze detection method based on a Purkinje image caused by reflection of irradiation light on a cornea may be used.

More specifically, a gaze detection process based on a pupil-cornea reflection method is performed. A gaze vector indicating the orientation (rotational angle) of the eye is calculated based on the pupil image contained in a captured image of the eye and a Purkinje image by using the pupil-cornea reflection method. Thus, the gaze of a user is detected.

The display apparatus according to the present embodiment may include an image capturing apparatus having a light receiving element and may control a display image of the display apparatus based on gaze information of a user from the image capturing apparatus.

The display apparatus determines a first display region at which the user gazes and a second display region other than the first display region in accordance with the gaze information. A first display region and a second display region may be determined by the controller of the display apparatus or a first display region and a second display region determined by an external controller may be received. In a display region of the display apparatus, a display resolution of the first display region may be controlled so as to be higher than a display resolution of the second display region. In other words, the resolution of the second display region may be made lower than the resolution of the first display region.

A display region includes a first display region and a second display region different from the first display region. A region having a higher priority is determined in accordance with gaze information from among the first display region and the second display region. A first field of view region and a second field of view region may be determined by the controller of the display apparatus or a first field of view region and a second field of view region determined by an external controller may be received. The resolution of the region having a higher priority may be controlled so as to be provided with a higher resolution than a region other than the region having a higher priority. In other words, the resolution of a region having a relatively lower priority may be decreased.

Artificial intelligence (AI) may be used to determine a first display region or a region having the higher priority. AI may be a model configured to estimate an angle of gaze and a distance to an object ahead of the gaze from an image of an eye by using the images of the eye and corresponding directions in which the eye of the image is actually viewing as training data. The display apparatus, or the image capturing apparatus, or an external apparatus may include an AI program. When the external apparatus includes an AI program, the information of the first display region or the region having the higher priority is transmitted to the display apparatus via communication.

When display control is performed based on gaze detection, the display apparatus is suitably applicable to smart glasses further including an image capturing apparatus that captures an outside image. The smart glasses are capable of displaying outside information that is captured in real time.

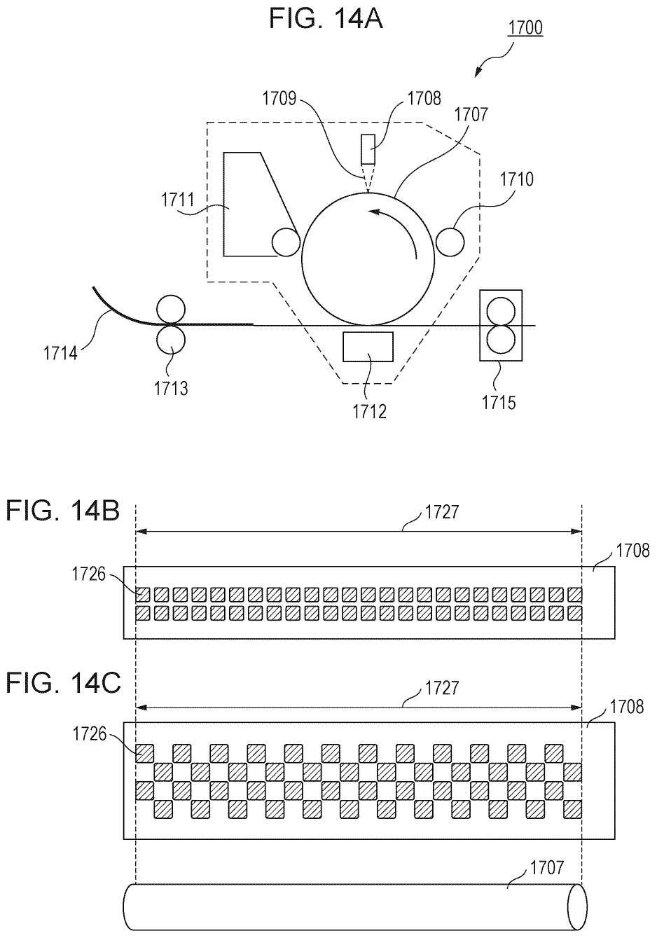

FIGS. 14A to 14C show an image forming apparatus. FIG. 14A is a schematic view of the image forming apparatus 1700 according to the present embodiment. The image forming apparatus 1700 includes a photoconductor, an exposure light source, a developing portion, a charging portion, a transfer unit, conveying rollers, and a fuser.

Light 1709 is applied from the exposure light source 1708, and an electrostatic latent image is formed on the surface of the photoconductor 1707. The exposure light source 1708 includes an organic light emitting element. The developing portion 1711 has toner and the like. The charging portion 1710 electrostatically charges the photoconductor 1707. The transfer unit 1712 transfers the developed image to a print medium 1714. The conveying rollers 1713 convey the print medium 1714. The print medium 1714 is, for example, paper. The fuser 1715 fixes the image formed on the medium 1714.

FIGS. 14B and 14C are schematic views that show the layout of a plurality of light emitting portions 1726 on a long substrate in the exposure light source 1708. The arrow 1727 indicates a direction parallel to the axis of the photoconductor 1707 and represents a column direction in which the light emitting portions 1726 each having an organic light emitting element are arranged. This column direction is the same as the direction of the axis around which the photoconductor 1707 rotates. This direction can also be referred to as a major-axis direction of the photoconductor 1707.

FIG. 14B shows a mode where the light emitting portions 1726 are arranged along the major-axis direction of the photoconductor 1707. FIG. 14C illustrated a different mode than FIG. 14B, showing a mode where the light emitting portions 1726 are alternately arranged in the column direction for each of the first and second columns. The light emitting portions 1726 are arranged at different positions in the row direction between the first column and the second column.

The first column has a plurality of the light emitting portions 1726 arranged with spaces therebetween. The second column has the light emitting portions 1726 at positions corresponding to the spaces between the light emitting portions 1726 of the first column. In other words, a plurality of the light emitting portions 1726 is arranged with spaces therebetween in both the column and row directions.

The arrangement of FIG. 14C can be described as, for example, a grid pattern arrangement, a staggered pattern arrangement, or a checkerboard pattern arrangement.

As described above, with an apparatus using the organic light emitting elements according to the present embodiment, stable display can be performed for an extended duration, with good image quality.

According to certain aspects of the present disclosure, peeling of the protective layer or the insulating layer from the slit is suppressed and yield is improved.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2024-197910, filed Nov. 13, 2024 and No. 2025-136387, filed Aug. 19, 2025, which are hereby incorporated by reference herein in their entirety.

1. An element substrate comprising:
an effective element region including a plurality of function elements; and
a peripheral region along a surface of the element substrate,
wherein the peripheral region surrounds the effective element region,
wherein the element substrate includes:
a wiring layer electrically connected to the plurality of function elements,
an external connecting terminal, and
an insulating layer covering the function elements and the wiring layer, wherein the insulating layer has a slit between the external connecting terminal and an edge of the element substrate, and
resin is disposed in the slit.

2. The element substrate according to claim 1, wherein, viewed perpendicular to the surface, the slit is disposed along the edge, in the peripheral region.

3. The element substrate according to claim 1, further comprising:
a guard ring, wherein:
the guard ring includes a plurality of wiring layers and a plug configured to connect the wiring layers,
the plug is disposed in the peripheral region,
the plug is at least one of a via plug and a contact plug, and
the slit overlaps the guard ring, viewed perpendicular to the surface.

4. The element substrate according to claim 1, further comprising:
a guard ring, wherein:
the guard ring includes a plurality of wiring layers and a plug configured to connect the wiring layers,
the plug is disposed in the peripheral region,
the plug is at least one of a via plug and a contact plug, and
at least part of the slit is disposed outside the guard ring, viewed perpendicular to the surface.

5. The element substrate according to claim 1, wherein, viewed perpendicular to the surface, at least the two slits are disposed at a predetermined interval.

6. The element substrate according to claim 1, wherein:
a second substrate covers the effective element region, and
the second substrate is joined to the element substrate with the resin disposed in the slit.

7. The element substrate according to claim 1, wherein:
viewed perpendicular to the surface, a width of the slit in at least part of a corner portion of the element substrate is wider than a width in a straight portion other than the corner portion.

8. The element substrate according to claim 1, wherein each function element of the plurality of function elements is an organic light emitting element.

9. The element substrate according to claim 1, wherein:
the wiring layer is disposed within an insulating layer,
the slit extends into the insulating layer, and
a bottom portion of the slit aligns with the wiring layer.

10. The element substrate according to claim 1, wherein:
the wiring layer is disposed within an insulating layer,
a conductive layer is disposed within the insulating layer, and
a bottom portion of the slit contacts the conductive layer.

11. The element substrate according to claim 10, wherein the conductive layer aligns with the wiring layer.

12. The element substrate according to claim 1, wherein the insulating layer has a Low-k film, and the slit penetrates the Low-k film.

13. A module comprising:
the element substrate according to claim 1;
a circuit substrate; and
a joining member configured to join the circuit substrate and the external connecting terminal of the element substrate,
wherein the external connecting terminal is configured to perform external communication.

14. The module according to claim 13, wherein the joining member is disposed in a hole formed in the insulating layer.

15. The module according to claim 14, wherein the joining member is an anisotropic conductive resin.

16. A display apparatus comprising:
the element substrate according to claim 8; and
a plurality of pixels, wherein at least one pixel of the plurality of pixels includes the organic light emitting element and a transistor connected to the organic light emitting element.

17. A photoelectric conversion apparatus comprising:
the element substrate according to claim 8;
an optical unit having a plurality of lenses;
an image pickup element configured to receive light having passed through the optical unit; and
a display unit configured to display an image captured by the image pickup element, wherein
the display unit includes the organic light emitting element.

18. An electronic device comprising:
the element substrate according to claim 8;
a display unit including the organic light emitting element;
a housing in which the display unit is provided; and
a communication unit provided in the housing and configured to communicate with an external source.

19. An illumination apparatus comprising:
the element substrate according to claim 8;
a light source including the organic light emitting element; and
a light diffusion unit or an optical film configured to transmit light emitted from the light source.

20. A moving object comprising:
the element substrate according to claim 8;
a lamp including the organic light emitting element; and
a body on which the lamp is provided.
